(19) United States
(12) Patent Application Publication
(10) Pub. No.: US 2010/0144088 A1
(43) Pub. Date: Jun. 10, 2010

(54) METHOD FOR FORMING METAL OXIDE AND METHOD FOR FORMING TRANSISTOR STRUCTURE WITH THE SAME

(75) Inventors: Jiyoung Oh, Daejeon (KR); Jonghyurk Park, Daegu (KR); Seung Youl Kang, Daejeon (KR); Chul Am Kim, Seoul (KR); In-Kyu You, Daejeon (KR); Kyoung Ik Cho, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Daejeon (KR)

(21) Appl. No.: 12/631,206

(22) Filed: Dec. 4, 2009

(30) Foreign Application Priority Data
Dec. 5, 2008 (KR) 10-2008-0123211
Apr. 8, 2009 (KR) 10-2009-0030256

(51) Int. Cl. H01L 21/328; C01G 9/02

(52) U.S. Cl. 438/104; 423/622; 257/E21.35

(57) ABSTRACT

Provided is a method for forming a metal oxide. A method for forming a metal oxide according to embodiments of the present invention includes preparing a metal oxide precursor solution including a dopant chemical species, preparing an alcohol-based solution including a basic chemical species, reacting the alcohol-based solution with the metal oxide precursor solution to form a reactant, and purifying the reactant to form a metal oxide.

### CROSS-REFERENCE TO RELATED APPLICATIONS

This U.S. non-provisional patent application claims priority under 35 U.S.C. §119 of Korean Patent Application Nos. 10-2008-0123211, filed on Dec. 5, 2008, and 10-2009-0030256, filed on Apr. 8, 2009, the entire contents of which are hereby incorporated by reference.

### BACKGROUND OF THE INVENTION

The present invention disclosed herein relates to a method for forming metal oxide and a transistor structure with the same, and more particularly, to a method for forming metal oxide by a solution treatment at room temperature, and a method for forming a transistor structure with the same.

Generally, zinc oxide (ZnO) has been a prominently-used metal oxide material in thin film transistor (TFT) LCDs, solar cells, organic electro luminescence (OEL), light emitting diodes (LED), optical apparatuses, and gas sensors.

Methods for forming zinc oxide may include chemical vapor deposition (CVD), metal organic-chemical vapor deposition (MO-CVD), molecular beam epitaxy, plasma synthesis, and sputtering deposition. However, the above methods require expensive equipment. Another method for forming zinc oxide is a colloid (sol-gel) synthesis method. The sol-gel synthesis method does not require expensive equipment, unlike other methods for forming zinc oxide. However, the sol-gel synthesis method requires much time to form zinc oxide and provides low yield of zinc oxide. In addition, zinc oxide formed by the above methods shows low stability to light.

A transistor structure in a thin film transistor display has a semiconductor layer used as a channel forming layer. The semiconductor layer may be formed using metal oxide as described above. For example, the semiconductor layer may be formed by supplying a solution including zinc oxide on a substrate, and then performing a sintering treatment. The sintering treatment may include light treatment, UV treatment, oxidation treatment, or heat treatment.

### SUMMARY OF THE INVENTION

The present invention provides a method for efficiently forming metal oxide and a method for forming a transistor structure with the same.

The present invention also provides a method for forming metal oxide without using expensive equipment and a method for forming a transistor structure with the same.

The present invention also provides a method for forming metal oxide with improved stability to light and a method for forming a transistor structure with the same.

Embodiments of the present invention provide methods for forming metal oxide including preparing metal oxide precursor solution including a dopant chemical species, preparing an alcohol-based solution including a basic chemical species, reacting the alcohol-based solution with the metal oxide precursor solution to form a reactant, and purifying the reactant to form metal oxide.

In some embodiments, the dopant chemical species may include at least one selected from the group consisting of gallium (Ga), aluminum (Al), indium (In), germanium (Ge), tin (Sn), antimony (Sb), phosphorous (P), and arsenic (As).

In other embodiments, the dopant chemical species may be within about 10 wt % based on the metal oxide precursor solution.

In still other embodiments, the dopant chemical species may further include at least one selected from the group consisting of aluminum (Al), copper (Cu), nickel (Ni), and iridium (Ir).

In other embodiments of the present invention, methods for forming a transistor structure include preparing metal oxide precursor solution including a dopant chemical species, preparing an alcohol-based solution including a basic chemical species, reacting the alcohol-based solution with the metal oxide precursor solution to form a reactant, purifying the reactant to form metal oxide, and forming metal oxide semiconductor layer used as a channel forming layer on a substrate with the metal oxide.

In even other embodiments of the present invention, the dopant chemical species may include at least one selected from the group consisting of gallium (Ga), aluminum (Al), indium (In), germanium (Ge), tin (Sn), antimony (Sb), phosphorous (P), and arsenic (As).

In yet other embodiments of the present invention, the dopant chemical species may further include at least one selected from the group consisting of aluminum (Al), copper (Cu), nickel (Ni), and iridium (Ir).

In further embodiments of the present invention, the forming of a metal oxide semiconductor layer on the substrate may include rotating the substrate and applying the metal oxide on the substrate which is rotated.

In still further embodiments of the present invention, methods for forming a transistor structure may further include forming a gate electrode pattern on the substrate, forming an insulation layer covering the gate electrode pattern, and forming a source and drain on the insulation layer, and the forming of the metal oxide semiconductor layer may include supplying the metal oxide on the substrate with the source and drain formed.

In even further embodiments of the present invention, the forming of the source and drain may include forming a source and drain layer on the insulation layer and forming a trench exposing the insulation layer to the source and drain layer, and the forming of the metal oxide semiconductor layer may include forming a zinc oxide layer filling the trench and patterning the zinc oxide layer.

In some embodiments, a zinc oxide doped by a solution treatment may be formed. Accordingly, the present invention may form an easily doped metal oxide.

In other embodiments, a zinc oxide doped at relatively low temperatures may be formed. Accordingly, because the present invention does not require any device to provide a high-temperature atmosphere, it may curtail costs of manufacturing metal oxide.

In still other embodiments, zinc oxide doping concentration may be easily controlled. Accordingly, the present invention may efficiently manufacture a zinc oxide with a doping concentration appropriate for a semiconductor layer of a transistor structure.

In even other embodiments, a semiconductor layer as a channel forming layer of a transistor structure may be formed at room temperature. Accordingly, because the present invention does not require any device to provide a high-temperature atmosphere, it may curtail costs of manufacturing a transistor structure.

In yet other embodiments, a semiconductor layer as a channel forming layer of a transistor structure may be formed by a solution treatment. Accordingly, the present invention may form a semiconductor layer easily.

In further embodiments, a semiconductor layer as a channel forming layer of a transistor structure may be formed without any sintering process of metal oxide.

In still further embodiments, the stability of a semiconductor layer used as a channel forming layer of a transistor structure to light may be improved.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a schematic view illustrating a transistor structure according to embodiments of the present invention;

FIG. 2 is a flowchart illustrating a method for forming metal oxide according to embodiments of the present invention;

FIG. 3 is a flowchart illustrating a method for forming a transistor structure according to embodiments of the present invention;

FIG. 4 is a graph illustrating a change of a gate voltage (Vg)-drain current (Id) of a zinc oxide formed by a method for forming metal oxide according to embodiments of the present invention;

FIG. 5 is a SEM image of the semiconductor layer shown in FIG. 1; and

FIG. 6 is an image illustrating a cross section of the semiconductor layer shown in FIG. 5.

### DETAILED DESCRIPTION OF PREFERRED EMBODIMENTS

A method for forming metal oxide and a transistor structure with the same in preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

In the figures, the dimensions of substrates, layers and regions are exaggerated for clarity of illustration. It will also be understood that when an object is referred to as being ‘on’ another object, it can be directly on the other object or disposed apart from the other object. Further, it will be understood that when an object is disposed apart from another object, one or more intervening objects may also be disposed between the object and the other object. Like reference numerals refer to like elements throughout.

Hereinafter, an exemplary embodiment of the present invention will be described in conjunction with the accompanying drawings.

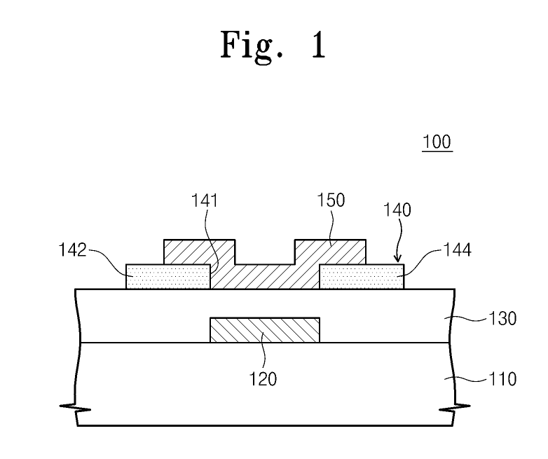

FIG. 1 is a schematic view illustrating a transistor structure according to embodiments of the present invention.

Referring to FIG. 1, a transistor structure 100 according to embodiments of the present invention may have a bottom gate structure. For example, a transistor structure 100 according to embodiments of the present invention may include a gate electrode 120, an insulation layer 130, a source and drain 140, and a semiconductor layer 150 on a substrate 110.

The substrate 110 may be a base to form the transistor structure 100. The substrate 110 may be one of a semiconductor substrate, a transparent substrate, and a plastic substrate. For example, the substrate 110 may include either glass substrate or plastic substrate for manufacturing a display device.

The gate electrode 120 may be disposed in the insulation layer 130. The gate electrode 120 may be formed of a conductive material. For example, the gate electrode 120 may include organic semiconductor and polymer semiconductor materials. For another example, the gate electrode 120 may include a metal material. For example, the gate electrode 120 may include at least one selected from the group consisting of aluminum (Al), copper (Cu), molybdenum (Mo), tungsten (W), chromium (Cr), and platinum (Pt).

The source and drain 140 may be disposed on the insulation layer 130. The source and drain 140 may include a source electrode 142 and a drain electrode 144. The source electrode 142 and the drain electrode 144 may be disposed to be spaced apart. For example, the source and drain 140 may have a trench 141 exposing the insulation layer 130 to define the source electrode 142 and the drain electrode 144. The source and drain 140 may be formed of the same conductive material. For example, the source and drain 140 may be formed of a metal material. More specifically, the conductive material may include at least one selected from the group consisting of aluminum (Al), copper (Cu), molybdenum (Mo), tungsten (W), chromium (Cr), and platinum (Pt).

The semiconductor layer 150 may be disposed on the insulation layer 130 and the source and drain 140. For example, the semiconductor layer 150 may be disposed on the source electrode 142 and the drain electrode 144, while filling the trench 141. The semiconductor layer 150 may include metal oxide. For example, the semiconductor layer 150 may be formed of a material including zinc oxide (ZnO). That is, the semiconductor layer 150 may be a zinc oxide film. The semiconductor layer 150 may be formed by using zinc oxide nanoparticles doped with gallium prepared by a solution treatment.

Subsequently, a method for forming metal oxide according to embodiments of the present invention will be described in detail. The method for forming metal oxide may be used for forming zinc oxide nanoparticles doped with gallium so as to form a semiconductor layer 150 of the above-described transistor structure 100.

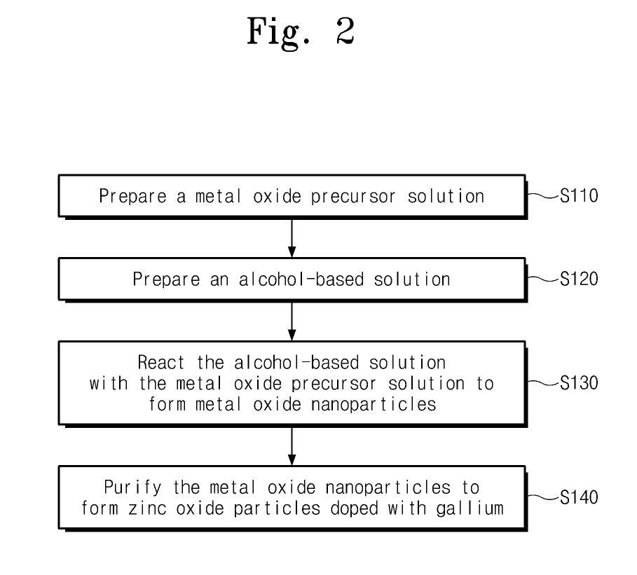

FIG. 2 is a flowchart illustrating a method for forming metal oxide according to embodiments of the present invention. Referring to FIG. 2, a metal oxide precursor solution may be prepared S110. The process of preparing a metal oxide precursor solution may include a process of mixing a solvent with a metal metal oxide precursor. The metal oxide precursor may include metal acetate, metal alkoxide, metal nitrate, metal halide, any hydrate thereof, and any combination thereof. The metal oxide precursor may include a dopant chemical species. The dopant chemical species may be used to control electrical and optical characteristics of metal oxide particles. The dopant chemical species may include at least one metal material selected from the group consisting of Group IIA metal, Group IIIA metal, Group IVA metal, Group VA metal, transition metal, lanthanide metal, actinide metal, and any combination thereof. For example, the dopant chemical species may include at least one selected from the group consisting of gallium (Ga), indium (In), germanium (Ge), tin (Sn), antimony (Sb), phosphorous (P), and arsenic (As). The dopant chemical species may also include at least one selected from the group consisting of aluminum (Al), copper (Cu), nickel (Ni), and iridium (Ir). This dopant chemical species may be added in an amount of about 0.1 wt % to about 10.0 wt % based on a total weight. The solvent may include alcohol. The alcohol may include methanol, ethanol, n-propanol, isopropanol, and any mixture thereof. For example, the dopant chemical species may include aluminum (Al), copper (Cu), nickel (Ni), iridium (Ir), and compounds thereof.

For example, the process of preparing a metal oxide precursor solution may include a process of dissolving 4.43 g of zinc acetate (Zn(C₂H₃O₂)₂) and 0.08 g of gallium nitrate hydrate in 37.5 g of methanol (CH₃OH).

A basic chemical species may be reacted with alcohol to prepare an alcohol-based solution 5120. The basic chemical species may include lithium hydroxide (LiOH), sodium hydroxide (NaOH), potassium hydroxide (KOH), ammonium hydroxide (NH₄OH), any hydrate thereof, and any combination thereof. The alcohol may include methanol, ethanol, n-propanol, isopropanol, and any mixture thereof. For example, the process of preparing an alcohol-based solution may include a process of dissolving 2.22 g of the potassium hydroxide in 19.5 ml of the methanol.

The process of preparing an alcohol-based solution may further include a process of mixing water (H₂O) and an organic solvent with a reactant including a basic chemical species and alcohol. For example, the organic solvent may include acetone, methyl ethyl ketone, tetrahydrofuran, benzene, toluene, o-xylene, m-xylene, p-xylene, methylene, diethyl ether, dichloromethane, chloroform, and any mixture thereof.

The alcohol-based solution including a basic chemical species may be reacted with the metal oxide precursor solution to form metal oxide nanoparticles S130. For example, the process of forming metal oxide nanoparticles may include mixing and reacting the alcohol-based solution including a basic chemical species with the metal oxide precursor solution to form a reactant. The process of forming a reactant may be performed by using an ultrasonic reactor. For example, an ultrasonic wave with a frequency of about 20 kHz to about 70 kHz may be applied to react a mixture of the alcohol-based solution including the basic chemical species with the metal oxide precursor solution. The ultrasonic wave to react the mixture may be either pulse type or continuous type. Time to perform an ultrasonic reaction of the mixture may be controlled within about 1 hour to about 24 hours. Through these processes, metal oxide nanoparticles may be formed. It is desirable to maintain a reactor, in which the mixture is to be reacted, at a constant temperature. For this purpose, a cooling device to maintain the mixture at a constant temperature may be provided in the reactor.

The metal oxide nanoparticles may be purified to form zinc oxide particles doped with gallium S140. More specifically, the reactant may be centrifuged to remove solvents and other by-products from the reactant. The reactant that has undergone the centrifugation may be dispersed in methanol, followed by centrifugation again to thereby remove solvents and other by-products from the reactant. These centrifugation processes may be repeated several times. Accordingly, purified zinc oxide particles doped with gallium may be formed. The zinc oxide particles doped with gallium may be in the nano-size range. The particle sizes of the zinc oxide doped with gallium may be controlled according to the reaction temperature and time.

Hereinafter, a method for forming a transistor structure according to embodiments of the present invention will be described in detail. The method for forming a transistor structure may include the above method for forming metal oxide. Accordingly, what has been repeatedly explained about the above method for forming metal oxide may be omitted or simplified.

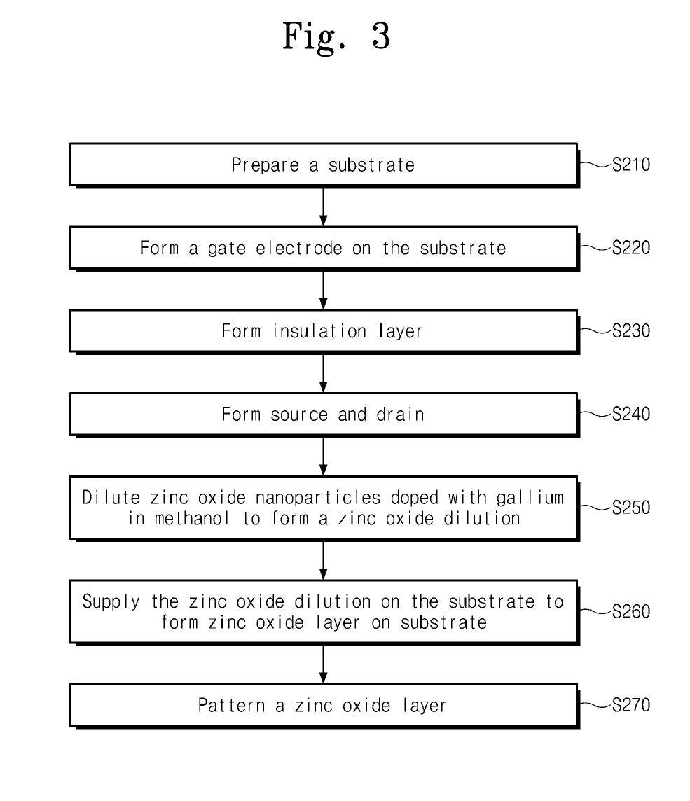

FIG. 3 is a flowchart illustrating a method for forming a transistor structure according to embodiments of the present invention. Referring to FIGS. 1 and 3, a substrate 110 may be prepared S210. For example, the process of preparing a substrate 110 may include a process of preparing a transparent substrate. For example, the process of preparing a substrate 110 may include a process of preparing a glass substrate (for example, glass) for manufacturing a display device. For another example, the process of preparing a substrate 110 may include a process of preparing either plastic substrate or silicon substrate. The process of preparing a substrate 110 may further include a process of forming a buffer layer (not shown) on the substrate 110. The process of forming a buffer layer may include a process of forming an oxide layer on the substrate 110.

A gate electrode 120 may be formed on the substrate 110 S220. For example, the process of forming a gate electrode 120 may include a process of forming a gate conductive layer on the substrate 110 and patterning the gate conductive layer. The process of forming a gate conductive layer may include a process of applying a conductive material on the substrate 110. For example, the conductive material may include organic semiconductor materials and polymer semiconductor materials. For another example, the conductive material may include at least one selected from the group consisting of aluminum (Al), copper (Cu), molybdenum (Mo), tungsten (W), chromium (Cr), and platinum (Pt).

An insulation layer 130 may be formed S230. The process of forming an insulation layer 130 may include a process of forming an insulation layer covering the gate electrode 120 on the substrate 110. The process of forming an insulation layer may include a process of forming at least one selected from the group consisting of silicon oxide, silicon nitride, and silicon oxynitride.

A source and drain 140 may be formed S240. The process of forming a source and drain 140 may include a process of forming a source and drain layer on the insulation layer 130 and forming a trench 141 exposing the insulation layer 130 to the source and drain layer. Accordingly, a source electrode 142 and a drain electrode 144 which are spaced apart may be formed on the insulation layer 130.

A semiconductor layer 150 may be formed. The process of forming a semiconductor layer 150 may be performed by a solution treatment. The solution treatment may be defined as a treatment of all the materials to be used in a solution state when a material to be formed (that is, a semiconductor layer 150) is formed. In the embodiment, the process of forming a semiconductor layer 150 will be described in detail by using the case where zinc oxide nanoparticles doped with gallium which are manufactured by the method for forming metal oxide described with reference to FIG. 2 are used. Hereinafter, a process of forming a semiconductor layer 150 according to one example of the present invention will be described in detail.

Zinc oxide nanoparticles doped with gallium may be diluted in methanol to form a zinc oxide dilution S250. The zinc oxide nanoparticles doped with gallium may be formed by performing the above method for forming metal oxide. When the zinc oxide nanoparticles doped with gallium are diluted in the methanol, the zinc oxide nanoparticles doped with gallium may be dispersed in the methanol.

The zinc oxide dilution may be supplied on the substrate 110 to form a zinc oxide layer on the substrate 110 S260. For example, the zinc oxide dilution may be applied on the substrate 110 while the substrate 110 is rotated. Otherwise, the zinc oxide dilution may be selectively applied on a part of the substrate 110 while the substrate 110 stops rotating. For another example, the process of forming a zinc oxide layer may be performed by immersing the substrate 110 in a container filled with the zinc oxide dilution. For still another example, the process of forming a zinc oxide layer may include a process of providing the zinc oxide dilution on the substrate 110 by a spray method, a screen printing, and a gravure coating method. Accordingly, a zinc oxide layer covering the source and drain 140 may be formed on the substrate 110. The zinc oxide layer may fill a trench 141 of the source and drain 140. Then, the thickness of the zinc oxide layer may be about 5 nm to about 500 nm.

The zinc oxide layer may be patterned 5270. For example, the process of patterning a zinc oxide layer may be performed by using an inkjet printing method or a masking technique. For another example, the process of patterning a zinc oxide layer may be performed by using a photolithography method. Accordingly, a semiconductor layer 150 may be formed on the substrate 110. When the semiconductor layer 150 is formed by using the above inkjet printing method, the masking technique, and the photolithography method, a subsequent process such as a heat treatment of the substrate 110 may not be required. Thus, the above solution treatment process of forming the semiconductor layer 150 may be performed under a process atmosphere at relatively low temperatures. For example, all the steps as described above (S250 to S270) may be performed under a room temperature atmosphere.

The following table is an analysis result of zinc oxide particles synthesized at each doping concentration in the present invention by an electron spectroscopy for chemical analysis (ESCA). For example, the following table shows concentration variations of zinc oxide nanoparticles according to mass changes of zinc and gallium.

Concentration variations
of zinc oxide
nanoparticles (wt %)

| | 2% | 3% | 4% | 5% |
|---|---|---|---|---|
| Zinc (Zn) | 98.38 | 97.62 | 96.92 | 96.84 |
| Gallium (Ga) | 1.62 | 2.38 | 3.08 | 3.16 |

Referring to the table, it can be realized that the concentration of the metal oxide may be controlled according to mass changes of the zinc (Zn) and the gallium (Ga). Accordingly, masses of the zinc (Zn) and the gallium (Ga) may be controlled to effectively form a metal oxide which satisfies a concentration required for the process.

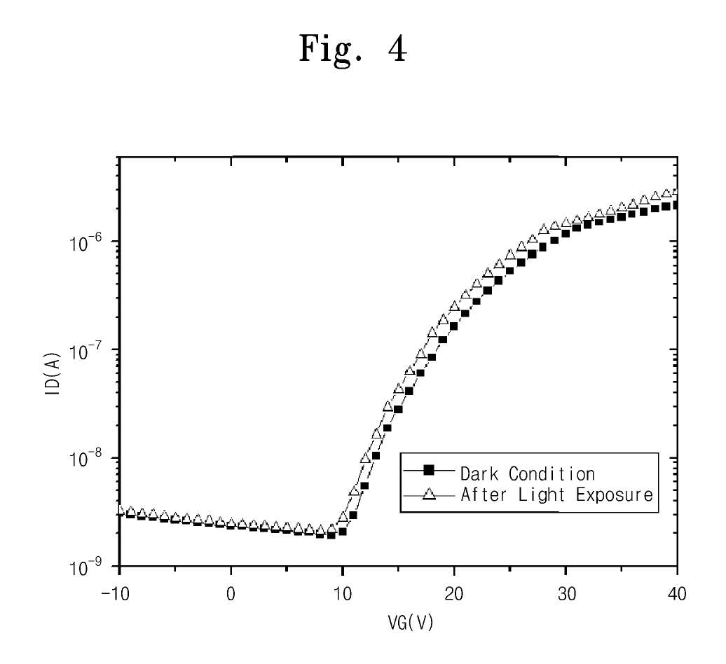

FIG. 4 is a graph illustrating a change of a gate voltage (Vg)-drain current (Id) of a zinc oxide formed by a method for forming metal oxide according to embodiments of the present invention. Referring to FIG. 4, it can be realized that a drain current (ID, ampere (A) unit) is changing according to a gate voltage (Vg, volt (V) unit). Accordingly, metal oxide manufactured by a method for forming metal oxide according to embodiments of the present invention is available as a semiconductor layer having improved stability to light.

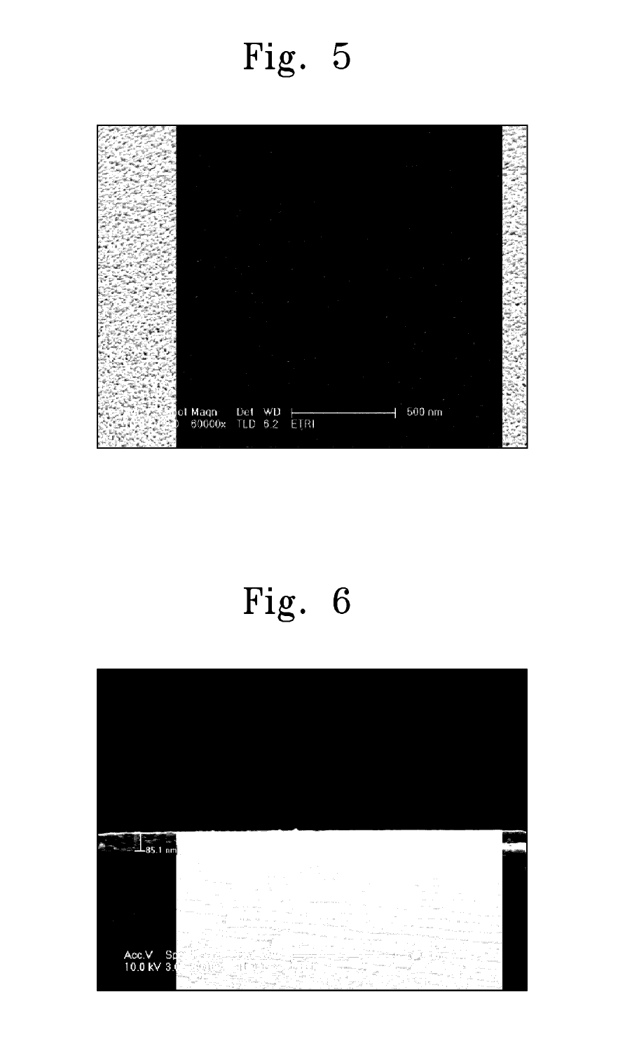

FIG. 5 is a SEM image of the semiconductor layer shown in FIG. 1, and FIG. 6 is an image illustrating a cross section of the semiconductor layer shown in FIG. 5. Referring to FIGS. 5 and 6, a semiconductor layer including metal oxide of nano-sized particles may be formed by a method for forming a transistor structure of the present invention.

According to embodiments of the present invention as described above, zinc oxide is formed by a solution treatment at relatively low temperatures, and then it may be used to form a metal oxide semiconductor layer as a channel forming layer of a transistor structure. Accordingly, metal oxide may be formed by a relatively simple and inexpensive method for forming metal oxide.

According to embodiments of the present invention, the amounts of zinc acetate and gallium nitrate hydrate supplied may be controlled to control the concentration of metal oxide easily.

According to embodiments of the present invention, because a semiconductor layer used as a channel forming layer of a transistor structure may be formed at room temperature by a chemical treatment method, a semiconductor layer as a channel forming layer of a transistor structure may be formed without any sintering process of metal oxide.

The foregoing detailed descriptions are to illustrate the concepts of the present invention. What has been described above is also to illustrate and describe the examples embodied so that the concepts of the present invention may be easily understood by those skilled in the art, and the present invention may be used in different combinations, modifications, and environments. That is, any changes and modifications of the present invention may be allowed within the scope of the invention disclosed in the specification, the equivalent scope of what has been described, and/or the scope of the technology or knowledge to which the art pertains. The above-described embodiments may be also embodied in different forms known in the art and various modifications required in the specific applications and uses of the present invention may be allowed. Thus, the above-disclosed embodiments in the detailed description of the invention are not intended to limit the present invention and the appended claims also include different embodiments. For example, the formation of a semiconductor layer with a transistor structure having a bottom gate structure was described. However, metal oxide formed by a method for forming metal oxide according to the present invention may be applied to a semiconductor layer with transistor structures having various structures. For example, the technology of the present invention may be used in the manufacture of a semiconductor layer with a transistor structure having a top gate structure.

What is claimed is:

1. A method for forming a metal oxide, comprising:
preparing a metal oxide precursor solution comprising a dopant chemical species;
preparing an alcohol-based solution comprising a basic chemical species;
reacting the alcohol-based solution with the metal oxide precursor solution to form a reactant; and
purifying the reactant to form a metal oxide.

2. The method of claim 1, wherein the dopant chemical species comprises at least one selected from the group consisting of gallium (Ga), indium (In), germanium (Ge), tin (Sn), antimony (Sb), phosphorous (P), and arsenic (As).

3. The method of claim 2, wherein the dopant chemical species is controlled in an amount of about 0.1 wt % to 10 wt % based on the metal oxide precursor solution.

4. The method of claim 2, wherein the dopant chemical species comprises at least one selected from the group consisting of aluminum (Al), copper (Cu), nickel (Ni), and iridium (Ir).

5. A method for forming a transistor structure, comprising:
preparing a metal oxide precursor solution comprising a dopant chemical species;
preparing an alcohol-based solution comprising a basic chemical species;
reacting the alcohol-based solution with the metal oxide precursor solution to form a reactant;
purifying the reactant to form a metal oxide; and
forming a metal oxide semiconductor layer used as a channel forming layer of a transistor structure on a substrate using the metal oxide.

6. The method of claim 5, wherein the forming of the metal oxide semiconductor layer on the substrate comprises:
rotating the substrate; and
applying the metal oxide on the substrate which is rotated.

7. The method of claim 5, wherein the forming of the metal oxide semiconductor layer on the substrate comprises:
selectively applying the metal oxide on a part of the substrate which stops rotating.

8. The method of claim 5, wherein the forming of the metal oxide semiconductor layer on the substrate comprises:
immersing the substrate in a container filled with metal oxide dilution.

9. The method of claim 5, wherein the forming of the metal oxide semiconductor layer on the substrate comprises:
providing metal oxide dilution on the substrate by a spray method, a screen printing or gravure coating method.

10. The method of claim 5, wherein the dopant chemical species comprises at least one selected from the group consisting of gallium (Ga), indium (In), germanium (Ge), tin (Sn), antimony (Sb), phosphorous (P), and arsenic (As).

11. The method of claim 10, wherein the dopant chemical species further comprises at least one selected from the group consisting of aluminum (Al), copper (Cu), nickel (Ni), and iridium (ir).

12. The method of claim 5, further comprising:
forming a gate electrode pattern on the substrate;
forming an insulation layer covering the gate electrode pattern; and
forming a source and drain on the insulation layer,
wherein the forming of the metal oxide semiconductor layer comprises supplying the metal oxide on the substrate with the source and drain formed.

13. The method of claim 12, wherein the forming of the source and drain comprises forming a source and drain layer on the insulation layer; and forming a trench in the source and drain layer to expose the insulation layer, and
wherein the forming of a metal oxide semiconductor layer further comprises forming a zinc oxide layer filling the trench; and patterning the zinc oxide layer.
